(19) United States
(12) Patent Application Publication
(10) Pub. No.: US 2023/0093664 A1
(43) Pub. Date: Mar. 23, 2023

(54) SILICON-CONTAINING COMPOSITION AND METHOD FOR MANUFACTURING SEMICONDUCTOR SUBSTRATE

(71) Applicant: JSR Corporation, Tokyo (JP)

(72) Inventors: Ryuichi Serizawa, Tokyo (JP); Kengo Hirasawa, Tokyo (JP); Akitaka Nii, Tokyo (JP)

(73) Assignee: JSR Corporation, Tokyo (JP)

(21) Appl. No.: 17/974,618

(22) Filed: Oct. 27, 2022

Related U.S. Application Data
(63) Continuation-in-part of application No. PCT/JP2021/017867, filed on May 11, 2021.

(30) Foreign Application Priority Data
May 21, 2020 (JP) 2020-089117

(51) Int. Cl. H01L 21/308; G03F 7/039; G03F 7/11; H01L 21/027; H01L 21/3065; H01L 21/311

(52) U.S. Cl. CPC H01L 21/3081; G03F 7/039; G03F 7/11; H01L 21/0276; H01L 21/0275; H01L 21/3086; H01L 21/3065; H01L 21/31144; H01L 21/31138

(57) ABSTRACT

A silicon-containing composition includes: a first polysiloxane; a second polysiloxane different from the first polysiloxane; and a solvent. The first polysiloxane includes a group which includes at least one selected from the group consisting of an ester bond, a carbonate structure, and a cyano group. The second polysiloxane includes a substituted or unsubstituted hydrocarbon group having 1 to 20 carbon atoms.

### CROSS-REFERENCE TO RELATED APPLICATIONS

The present application is a continuation-in-part application of International Application No. PCT/JP2021/017867, filed May 11, 2021, which claims priority to Japanese Patent Application No. 2020-089117, filed May 21, 2020. The contents of these applications are incorporated herein by reference in their entirety.

### BACKGROUND OF THE INVENTION

### Field of the Invention

The present invention relates to a silicon-containing composition and a method for manufacturing a semiconductor substrate.

### Description of the Related Art

For pattern formation in the manufacture of semiconductor substrates, for example, a multilayer resist process or the like is used in which a patterned substrate is formed by etching using, as a mask, a resist pattern obtained by exposing and developing a resist film laminated on a substrate via an organic underlayer film, a silicon-containing film, and the like (see, WO2012/039337).

### SUMMARY OF THE INVENTION

According to an aspect of the present invention, a silicon-containing composition includes: a first polysiloxane; a second polysiloxane different from the first polysiloxane; and a solvent. The first polysiloxane includes a group which includes at least one selected from the group consisting of an ester bond, a carbonate structure, and a cyano group. The second polysiloxane includes a substituted or unsubstituted hydrocarbon group having 1 to 20 carbon atoms.

According to another aspect of the present invention, a method for manufacturing a semiconductor substrate, includes directly or indirectly applying the above-described silicon-containing composition according to claim 1 to a substrate to form a silicon-containing film. A composition for forming a resist film is directly or indirectly applied to the silicon-containing film to form the resist film. The resist film is exposed to radiation. The exposed resist film is developed to form a resist pattern. The silicon-containing film is etched using the resist pattern as a mask to form a silicon-containing film pattern. Etching using the silicon-containing film pattern as a mask is performed. The silicon-containing film pattern is removed by a basic liquid.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4 - 7.2 as does the following list of values: 1, 4, 6, 10.

It has been found that upon further application of the multilayer resist process, the shape (rectangularity) of the resist pattern after the alkali development of the resist film may be impaired. In the process of manufacturing the semiconductor substrate or the like, the silicon-containing film may be removed using a removing liquid instead of etching from the viewpoint of reducing the influence on the substrate or the like during etching and improving production efficiency. However, it has also been found that the removal of the silicon-containing film by the removing liquid may be insufficient.

An embodiment of the present invention relates to a silicon-containing composition for forming a resist underlayer film which forms a pattern by etching using a resist pattern as a mask and is subjected to etching using the formed pattern as a mask and is removed by a basic liquid, wherein the silicon-containing composition contains two types of polysiloxanes and a solvent, wherein the two types of polysiloxanes are a first polysiloxane having a group containing at least one selected from the group consisting of an ester bond, a carbonate structure, and a cyano group, and a second polysiloxane having a substituted or unsubstituted hydrocarbon group having 1 to 20 carbon atoms.

The silicon-containing composition contains two types of specific polysiloxanes. As a result, when a silicon-containing film is formed from the silicon-containing composition, a resist pattern having excellent cross-sectional shape rectangularity can be formed, and the silicon-containing film can be easily removed by a basic liquid as a removing liquid (hereinafter, the cross-sectional shape rectangularity of the resist pattern is also referred to as “pattern rectangularity”, and the removability of the silicon-containing film is also referred to as “film removability”). The reason for this is not clear, but can be expected as follows. The change in the pattern rectangularity is considered to be caused by the fact that when the polarity of components in the silicon-containing film is high, a developer of the resist film infiltrates into the silicon-containing film, which causes the silicon-containing film to swell or reduces the adhesion of the silicon-containing film to the resist film, resulting in the deformation or collapse of the resist pattern. It is considered that deterioration in the film removability is caused by the fact that when the hydrophobicity of components in the silicon-containing film is high, the basic liquid as the removing liquid is less likely to permeate the silicon-containing film. When the hydrophobicity of the silicon-containing film is enhanced in consideration of the pattern rectangularity, the film removability is deteriorated, and when the polarity of the silicon-containing film is increased with emphasis on the film removability, the pattern rectangularity is deteriorated. Therefore, it can be said that both are in a so-called trade-off relationship. The first polysiloxane contained in the silicon-containing composition has the group containing at least one selected from the group consisting of an ester bond, a carbonate structure, and a cyano group (hereinafter, also referred to as a “polar group”), and has a structure with relatively high polarity. Meanwhile, the second polysiloxane has a substituted or unsubstituted hydrocarbon group having 1 to 20 carbon atoms (hereinafter, also referred to as a “hydrophobic group”), and has a structure with relatively high hydrophobicity. As described above, in the silicon-containing composition, the first polysiloxane having relatively high polarity and the second polysiloxane having relatively high hydrophobicity coexist, and thus when a silicon-containing film is formed, a balance between the polarity and hydrophobicity of the silicon-containing film can be achieved at a high level, which makes it possible to achieve both the pattern rectangularity and the film removability.

Furthermore, it is considered that when the silicon-containing film is formed, the hydrophobic second polysiloxane is unevenly distributed on the surface side in the film, and the polar first polysiloxane is unevenly distributed on the substrate side in the film. The uneven distribution structure of the two types of polysiloxanes in the silicon-containing film makes the surface side of the silicon-containing film hydrophobic to improve the pattern rectangularity, and after etching is performed using a silicon-containing film pattern as a mask, the second polysiloxane unevenly distributed on the surface side is removed by etching. This is presumed to also contribute to the enhancement of the film removability. The silicon-containing composition having the above-described unique properties can be suitably applied to the formation of the resist underlayer film which forms a pattern by etching using a resist pattern as a mask and is subjected to etching using the formed pattern as a mask and is removed by a basic liquid.

Another embodiment of the present invention relates to a method for manufacturing a semiconductor substrate, including

directly or indirectly applying the silicon-containing composition according to claim 1 to a substrate to form a silicon-containing film;

directly or indirectly applying a composition for forming a resist film to the silicon-containing film to form the resist film;

exposing the resist film to radiation;

developing the exposed resist film to form a resist pattern;

etching the silicon-containing film using the resist pattern as a mask to form a silicon-containing film pattern;

performing etching using the silicon-containing film pattern as a mask; and

removing the silicon-containing film pattern by a basic liquid.

In the manufacturing method, the silicon-containing composition is used to form the silicon-containing film as the underlayer of the resist film, and a resist pattern having an excellent rectangular cross-sectional shape can be formed, and the silicon-containing film can be easily removed using a basic liquid, therefore, high-quality semiconductor substrates can be efficiently manufactured.

Hereinafter, a silicon-containing composition and a method for manufacturing a semiconductor substrate according to embodiments of the present invention will be described in detail.

<Silicon-containing composition>

The silicon-containing composition according to the present embodiment contains two specific types of polysiloxanes (hereinafter, the two types of polysiloxanes are collectively referred to as “specific polysiloxanes”) and a solvent. The composition may contain other optional components (hereinafter also simply referred to as “optional components”) within a range that does not impair the effects of the present invention.

By containing the specific polysiloxane and the solvent, the silicon-containing composition can form a resist pattern having an excellent cross-sectional shape rectangularity when a resist pattern is formed on a silicon-containing film by alkali development. Furthermore, the silicon-containing film formed from the silicon-containing composition has excellent removability with a basic liquid. Since the silicon-containing composition exhibits the effects described above, it can be suitably used as a composition for forming a silicon-containing film (that is, a silicon-containing film forming composition).

In general, methods for developing a resist film are roughly classified into organic solvent development using an organic solvent as a developer and alkali development using an alkaline solution as a developer. Although the silicon-containing composition can be applied to both developing methods, it is preferably used for forming an underlayer film of a resist film to be alkali developed. When the silicon-containing composition is used to form an underlayer film of a resist film that is subjected to alkali development, only the exposed portion of the resist film is dissolved during alkali development after the resist film is formed and exposed, and the silicon-containing film, which is the underlayer film of the resist film, is not dissolved, and a resist pattern having an excellent cross-sectional shape rectangularity can be formed.

As the resist film to be alkali-developed, a positive resist film is particularly preferable, and a positive resist film for exposure with ArF excimer laser light (ArF exposure) or extreme ultraviolet (also referred to as “EUV”) (EUV exposure), which will be described later, is more preferable. In other words, the silicon-containing composition is suitably used for forming an underlayer film of an alkali-developable resist film for ArF exposure or EUV exposure.

### [Polysiloxane]

The silicon-containing composition contains two types of polysiloxanes, that is, a first polysiloxane and a second polysiloxane. As used herein, “polysiloxane” means a compound containing a siloxane bond (˜Si—O—Si-).

(First polysiloxane)

The first polysiloxane is polysiloxane having a polar group. In the present embodiment, the polar group is a group containing at least one selected from the group consisting of an ester bond, a carbonate structure and a cyano group (hereinafter also referred to as “ester bond or the like”). The ester bond includes not only the ester bond in the chain structure but also the ester bond incorporated in the cyclic structure (cyclic ester, that is, lactone structure). The carbonate structure includes not only a carbonate structure in a chain structure but also a carbonate structure incorporated in a cyclic structure (cyclic carbonate structure). By containing the first polysiloxane having a polar group, the silicon-containing composition can form a silicon-containing film with excellent film removability.

The silicon-containing composition can contain one or more first polysiloxanes. For example, it is possible to combine a first polysiloxane having a group containing an ester bond as a polar group and a first polysiloxane having a group containing a carbonate structure as a polar group.

The first polysiloxane preferably has a first structural unit represented by formula (1) below. The first polysiloxane may have structural units other than the first structural unit (hereinafter also simply referred to as “other structural units”) within a range that does not impair the effects of the present invention. Each structural unit of the first polysiloxane will be described below.

(First structural unit)

The first structural unit is a structural unit represented by the following formula (1). The first polysiloxane can have one or more first structural units. By having the polar group represented by X in the following formula (1), the first structural unit can form a silicon-containing film having excellent film removability.

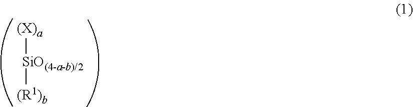

In the formula (1), X is a group containing at least one selected from the group consisting of an ester bond, a carbonate structure, and a cyano group, a is an integer of 1 to 3, when a is 2 or more, a plurality of Xs are the same or different from each other, R¹ is a monovalent organic group having 1 to 20 carbon atoms, a hydroxy group, or a halogen atom, b is an integer of 0 to 2, when b is 2, two Rls are the same or different from each other, and a +b is 3 or less.

As used herein, “organic group” means a group containing at least one carbon atom, and “carbon number” means the number of carbon atoms constituting the group.

In the formula (1), the polar group represented by X is not particularly limited as long as the polar group contains an ester bond or the like, but examples thereof include a monovalent organic group having 1 to 20 carbon atoms and containing an ester bond or the like. Examples of the mode of existence of the ester bond or the like include a structure in which one or more hydrogen atoms in the organic group are substituted with the ester bond or the like, a structure in which the ester bond or the like is incorporated between two carbon atoms, and a structure in which these structures are combined.

Examples of the monovalent organic group having 1 to 20 carbon atoms in the polar group represented by X in the formula (1) include a monovalent hydrocarbon group having 1 to 20 carbon atoms, a group containing a divalent heteroatom-containing group between carbon-carbon bonds of the hydrocarbon group (hereinafter, also referred to as a “group (a)”), a group obtained by substituting a part or all of hydrogen atoms of the hydrocarbon group or the group (α) with a monovalent heteroatom-containing group (hereinafter, also referred to as a “group (β), and a group obtained by combining the hydrocarbon group, the group (α) or the group W) with a divalent heteroatom-containing group (hereinafter, also referred to as a “group (Υ)”).

As used herein, the “hydrocarbon group” includes a chain hydrocarbon group, an alicyclic hydrocarbon group, and an aromatic hydrocarbon group. The “hydrocarbon group” may be a saturated hydrocarbon group or an unsaturated hydrocarbon group. The “chain hydrocarbon group” means a hydrocarbon group that does not include a cyclic structure and is composed only of a chain structure, and includes both a linear hydrocarbon group and a branched hydrocarbon group. The “alicyclic hydrocarbon group” means a hydrocarbon group that includes only an alicyclic structure as a ring structure and does not include an aromatic ring structure, and includes both a monocyclic alicyclic hydrocarbon group and a polycyclic alicyclic hydrocarbon group. However, it is not necessary for the alicyclic hydrocarbon group to be composed only of an alicyclic structure, and the alicyclic hydrocarbon group may include a chain structure in a part thereof. The “aromatic hydrocarbon group” means a hydrocarbon group that includes an aromatic ring structure as a ring structure. However, it is not necessary for the aromatic hydrocarbon group to be composed only of an aromatic ring structure, and the aromatic hydrocarbon group may include a chain structure or an alicyclic structure in a part thereof.

Examples of monovalent hydrocarbon groups having 1 to 20 carbon atoms include monovalent chain hydrocarbon groups having 1 to 20 carbon atoms, monovalent alicyclic hydrocarbon groups having 3 to 20 carbon atoms, and monovalent aromatic hydrocarbon groups having 6 to 20 carbon atoms.

Examples of monovalent chain hydrocarbon groups having 1 to 20 carbon atoms include alkyl groups such as a methyl group, an ethyl group, a n-propyl group, an i-propyl group, a n-butyl group, a sec-butyl group, an iso-butyl group, a tert-butyl group, alkenyl groups such as an ethenyl group, a propenyl group and a butenyl group, and alkynyl groups such as an ethynyl group, a propynyl group and a butynyl group.

Examples of monovalent alicyclic hydrocarbon groups having 3 to 20 carbon atoms include monocyclic saturated alicyclic hydrocarbon groups such as cyclopentyl group and cyclohexyl group, polycyclic alicyclic saturated hydrocarbon groups such as a norbornyl group, an adamantyl group, a tricyclodecyl group, a tetracyclododecyl group, monocyclic alicyclic unsaturated hydrocarbon groups such as a cyclopentenyl group and a cyclohexenyl group, polycyclic alicyclic unsaturated hydrocarbon groups such as a norbornenyl group, a tricyclodecenyl group, a tetracyclododesenyl group.

Examples of monovalent aromatic hydrocarbon groups having 6 to 20 carbon atoms include aryl groups such as a phenyl group, a tolyl group, a xylyl group, a naphthyl group and an anthryl group, aralkyl groups such as a benzyl group, a phenethyl group, a naphthylmethyl group and an anthrylmethyl group.

Examples of heteroatoms that constitute divalent and monovalent heteroatom-containing groups include oxygen atoms, nitrogen atoms, sulfur atoms, phosphorus atoms, silicon atoms, and halogen atoms. Halogen atoms include, for example, fluorine, chlorine, bromine and iodine atoms.

Divalent heteroatom-containing groups include, for example, —O—, —C(═O)—, —S—, —C(═S)—, —NR′—, or combinations of two or more of these and the like. R′ is a hydrogen atom or a monovalent hydrocarbon group.

Examples of monovalent heteroatom-containing groups include halogen atoms, a hydroxy group, a carboxy group, a cyano group, an amino group, a sulfanyl group, and the like.

The a is preferably 1 or 2, more preferably 1.

Examples of the monovalent organic group having 1 to 20 carbon atoms represented by R¹ include the same groups as those exemplified as the monovalent organic group having 1 to 20 carbon atoms for X described above.

The halogen atom represented by R¹ includes, for example, a fluorine atom, a chlorine atom, a bromine atom, and an iodine atom.

R¹ is preferably a monovalent chain hydrocarbon group, a monovalent aromatic hydrocarbon group, or a monovalent group in which a part or all of the hydrogen atoms of the monovalent hydrocarbon group are replaced with a monovalent heteroatom-containing group, more preferably an alkyl group or an aryl group, and further preferably a methyl group, an ethyl group or a phenyl group.

The b is preferably 0 or 1, more preferably 0.

X in the above formula (1) may be a group containing an ester bond. When X in formula (1) contains an ester bond, X is preferably represented by formula (2) below.

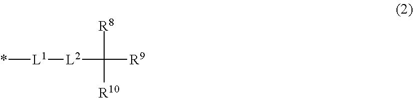

In formula (2) above, L¹ in the formula (2) is a single bond or a divalent linking group, * is a bond with a silicon atom in the formula (1), L² is **—OCO—or **—OCO—, ** is a bond with L¹, R⁸ is a hydrogen atom or a monovalent hydrocarbon group having 1 to 20 carbon atoms, and R⁹ and R¹⁹ each independently represent a monovalent chain hydrocarbon group having 1 to 10 carbon atoms or a monovalent alicyclic hydrocarbon group having 3 to 20 carbon atoms, or represent a divalent alicyclic group having 3 to 20 carbon atoms formed by these groups combined together and a carbon atom to which they are bonded.

Examples of the divalent linking group represented by L¹ include a divalent organic group having 1 to 10 carbon atoms. Examples of the divalent organic group having 1 to 10 carbon atoms include groups obtained by removing one hydrogen atom from monovalent organic groups having 1 to 10 carbon atoms among the groups exemplified as the monovalent organic groups having 1 to 20 carbon atoms in X in the above formula (1).

Among them, L¹ is preferably a single bond, a divalent hydrocarbon group having 1 to 10 carbon atoms, or a divalent heteroatom-containing group between the carbon-carbon bonds of a divalent hydrocarbon group having 1 to 10 carbon atoms, more preferably a single bond, an alkylene group, an alkenylene group, or a group containing -S- between carbon-carbon bond of an alkylene group.

As the monovalent hydrocarbon group having 1 to 20 carbon atoms represented by R⁸, the monovalent hydrocarbon groups having 1 to 20 carbon atoms exemplified for X in the above formula (1) can be suitably employed.

The monovalent chain hydrocarbon group having 1 to 10 carbon atoms represented by R⁹ and R¹⁰ preferably includes monovalent chain hydrocarbon groups having 1 to 10 carbon atoms among the monovalent chain hydrocarbon groups having 1 to 20 carbon atoms exemplified for X in the formula (1).

As the monovalent alicyclic hydrocarbon group having 3 to 20 carbon atoms represented by R⁹ and R¹⁰, the monovalent alicyclic hydrocarbon groups having 3 to 20 carbon atoms exemplified for X in the above formula (1) groups are preferred.

The divalent alicyclic group having 3 to 20 carbon atoms formed by these groups combined together and a carbon atom to which they are bonded is a group obtained by removing one hydrogen atom from the alicyclic hydrocarbon group of the monovalent alicyclic group having 3 to 20 carbon atoms represented by R⁹ and R¹⁰.

When the above L² is **—COO—, it is preferred that all of R⁸ to R¹⁰ are a monovalent chain hydrocarbon group, or R⁸ is a monovalent chain hydrocarbon group and R⁹ and R¹⁰ are combined together to form a divalent alicyclic group having 3 to 20 carbon atoms with a carbon atom to which they are bonded. In this case, the structure beyond L² preferably includes a tert-butyl group, a 1-methylcyclopentan-1-yl group, and the like.

When the above L² is **—OCO—, it is preferred that all of R⁸ to R¹⁰ are a hydrogen atom, or any one of R⁸ to R¹⁰ is a monovalent chain hydrocarbon group, and the remaining groups are hydrogen atoms. In this case, the structure beyond L² is preferably a methyl group.

From the viewpoint of film removability, the above L² is preferably **—OCO —.

Examples of the group containing a lactone structure as the ester bond in X of the above formula (1) include groups represented by the following formula (3).

*—L³—R⁵ (3)

In the formula (3), L³ is a single bond or a divalent linking group. R⁵ is a monovalent group having a lactone structure. indicates a bond with the silicon atom in the above formula (1).

Examples of the divalent linking group represented by L³ include the same groups as those exemplified for L¹ in the formula (2). L³ is preferably a single bond.

Examples of the lactone structure in R⁵ include monocyclic lactone structures such as a propiolactone structure, a butyrolactone structure, a valerolactone structure, a caprolactone structure, a cyclopentanelactone structure, a cyclohexanelactone structure, a polycyclic lactone structures such as a norbornanelactone structure, a benzobutyrolactone structure, and a benzovalerolactone structure. Among these, a monocyclic lactone structure is preferable, and a butyrolactone structure is more preferable.

Examples of the group containing a carbonate structure as an ester bond in X in the above formula (1) include a group containing a chain carbonate structure, a group containing a cyclic carbonate structure, and the like.

Examples of the group containing a chain carbonate structure include groups in which a carbonate structure is incorporated between adjacent carbon atoms in a monovalent chain hydrocarbon group having 1 to 20 carbon atoms. As the monovalent chain hydrocarbon group having 1 to 20 carbon atoms, the groups exemplified as the monovalent chain hydrocarbon group having 1 to 20 carbon atoms in X in the above formula (1) can be suitably employed.

Examples of the group containing the cyclic carbonate structure include groups represented by the following formula (4).

*—L⁴—R⁶ (4)

In the formula (4), L⁴ is a single bond or a divalent linking group. R⁶ is a monovalent group having a cyclic carbonate structure. indicates a bond with the silicon atom in the above formula (1).

Examples of the divalent linking group represented by L⁴ include the same groups as those exemplified as L¹ in formula (2) above. L⁴ is preferably a divalent alkylene group having 2 to 10 carbon atoms.

The cyclic carbonate structure for R⁶ includes monocyclic cyclic carbonate structures such as an ethylene carbonate structure, a trimethylene carbonate structure, and a tetramethylene carbonate structure, polycyclic carbonate structures such as a cyclopentylene carbonate structure, a cyclohexylene carbonate structure, a norbornylene carbonate structure, a phenylene carbonate structure, and a naphthylene carbonate structure, and the like. Among these, a monocyclic cyclic carbonate structure is preferred, and an ethylene carbonate structure is more preferred.

In the above formula (1), examples of the group containing a cyano group represented by X include groups in which one or more hydrogen atoms in a monovalent hydrocarbon group having 1 to 20 carbon atoms are substituted with a cyano group. As the monovalent hydrocarbon group having 1 to 20 carbon atoms, the monovalent hydrocarbon groups having 1 to 20 carbon atoms exemplified for X in the above formula (1) can be preferably employed. Among them, a group in which one or more hydrogen atoms in the monovalent chain hydrocarbon group having 1 to 10 carbon atoms is substituted with a cyano group is more preferable, and a cyanomethyl group and a 2-cyanoethyl group are particularly preferable.

From the viewpoint of film removability, X in the above formula (1) is preferably a group containing an ester bond.

As the first structural unit, for example, structural units derived from compounds represented by the following formulas (1-1) to (1-15) (hereinafter also referred to as “first structural unit (1) to first structural unit (15)”) and the like.

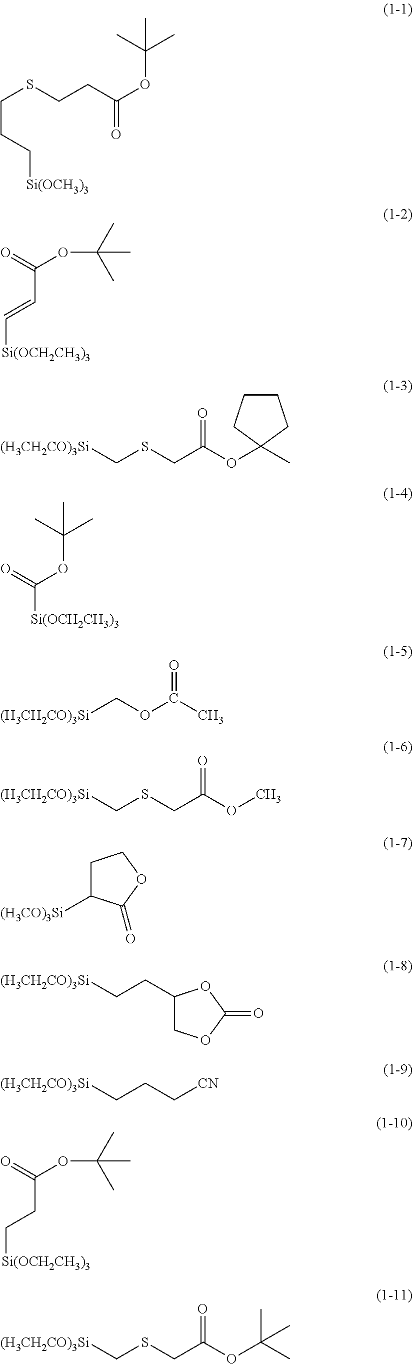

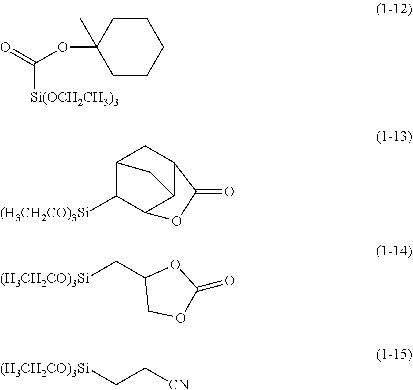

As the first structural unit, from the viewpoint of further improving the film removability, the first structural units (1) to (4) or the first structural units (10) to (12) are preferable, and the first structural units (1) to (4) are more preferred.

The lower limit of the content of the first structural unit in all structural units constituting the first polysiloxane is preferably 0.5 mol %, more preferably 1 mol %, and even more preferably 2 mol %. Moreover, the upper limit of the content of the first structural unit is preferably 40 mol %, more preferably 35 mol %, and even more preferably 30 mol %. When the content of the first structural unit is within the above range, a silicon-containing film having excellent film removability can be formed.

### (Third Structural Unit)

The first polysiloxane may have a third structural unit represented by the following formula (5) as a structural unit other than the first structural unit. By having the third structural unit, it is possible to exhibit an antireflection effect on the resist film during exposure and form a resist pattern having excellent cross-sectional rectangularity.

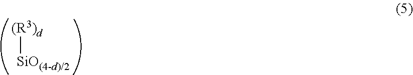

In the above formula (5), R³ is a substituted or unsubstituted aryl group having 6 to 20 carbon atoms. d is an integer of 1 to 3. When d is 2 or more, a plurality of Ras are the same or different from each other.

Examples of the aryl group having 6 to 20 carbon atoms represented by R³ include a phenyl group, a naphthyl group, an anthracenyl group, and the like.

Examples of substituents for the aryl group include alkyl groups having 1 to 5 carbon atoms, a hydroxy group, and a halogen atom. Among them, a halogen atom is preferred, and a fluorine atom is more preferred.

The third structural unit includes, for example, a structural unit derived from a compound represented by the following formulas (5-1) to (5-8) (hereinafter also referred to as “third structural unit (1) to third structural unit (8)”) and the like.

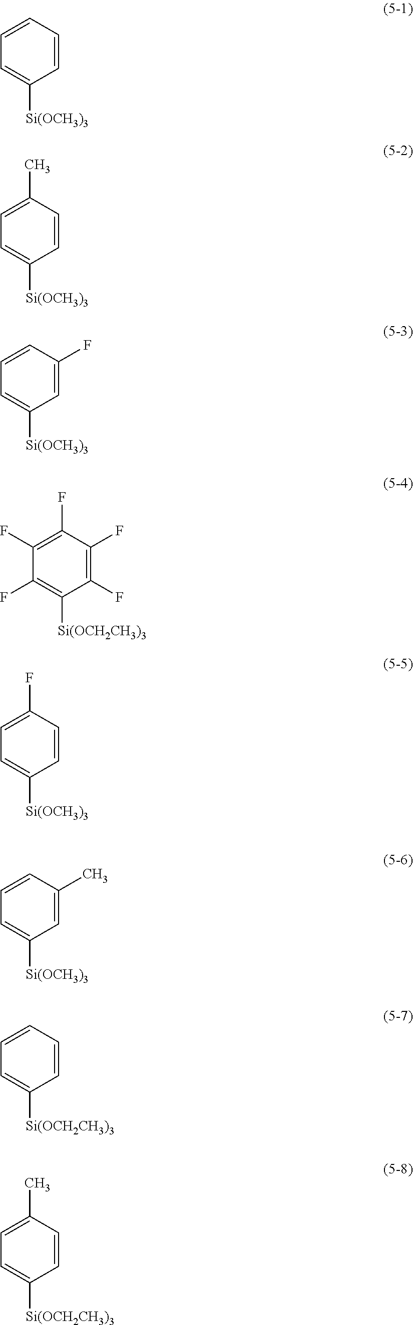

When the first polysiloxane has the third structural unit, the lower limit of the content of the third structural unit in all structural units constituting the first polysiloxane is preferably 5 mol %, more preferably 10 mol %, and further preferably 15 mol %. The upper limit of the content of the third structural unit is preferably 50 mol %, more preferably 40 mol %, and even more preferably 30 mol %. When the content of the third structural unit is within the above range, a silicon-containing film having more excellent antireflection performance can be formed.

### (Fourth Structural Unit)

The first polysiloxane may have a fourth structural unit represented by the following formula (6) as a structural unit other than the first structural unit. When the first polysiloxane has the fourth structural unit, the oxygen gas etching resistance of the silicon-containing film formed from the silicon-containing composition can be improved.

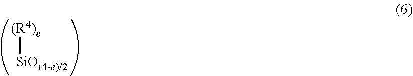

In the formula (6), R⁴ is a substituted or unsubstituted monovalent alkoxy group having 1 to 20 carbon atoms, a hydroxy group, or a halogen atom, e is an integer of 0 to 3, and when e is 2 or more, a plurality of R⁴s are the same or different from each other.

Specific examples of the monovalent alkoxy group having 1 to 20 carbon atoms represented by R⁴ in the above formula (6) include alkoxy groups such as a methoxy group, an ethoxy group, an n-propyloxy group, and an isopropoxy group. groups. Further, the halogen atom includes a fluorine atom, a chlorine atom, a bromine atom, an iodine atom and the like.

In the above formula (6), R⁴ is preferably an alkoxy group, more preferably a methoxy group.

When the first polysiloxane has the fourth structural unit, the lower limit of the content of the fourth structural unit in all structural units constituting the first polysiloxane is preferably 40 mol %, more preferably 45 mol %, even more preferably 50 mol %. The upper limit of the content of the fourth structural unit is preferably 95 mol %, more preferably 90 mol %, and even more preferably 85 mol %.

The lower limit of the content of the first polysiloxane in the total mass of the first polysiloxane and the second polysiloxane described below is preferably 40% by mass, more preferably 50% by mass, and even more preferably 60% by mass. The upper limit of the content is preferably 99% by mass, more preferably 98% by mass, and even more preferably 95% by mass. Thereby, the film removability can be improved while maintaining the pattern rectangularity.

The first polysiloxane may have a second structural unit that is incorporated into the second polysiloxane described later unless the film removability is affected. As long as the polysiloxane in the silicon-containing composition according to this embodiment has the first structural unit, it is treated as the first polysiloxane even if it has other structural units (for example, the second structural unit).

### (Second Polysiloxane)

The second polysiloxane is a polysiloxane having a hydrophobic group. In this embodiment, the hydrophobic group is a substituted or unsubstituted hydrocarbon group having 1 to 20 carbon atoms. By containing the second polysiloxane having a hydrophobic group, the silicon-containing composition can form a silicon-containing film capable of imparting excellent cross-sectional rectangularity to the resist pattern. The silicon-containing composition can contain one or more second polysiloxanes.

As the hydrocarbon group having 1 to 20 carbon atoms, the groups exemplified as the hydrocarbon group having 1 to 20 carbon atoms for X in the formula (1) can be preferably employed.

(Second structural unit)

The second polysiloxane preferably has a second structural unit represented by the following formula (7).

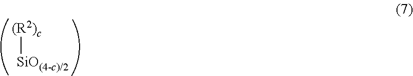

In the above formula (7), R² is a substituted or unsubstituted alkyl group having 1 to 10 carbon atoms. c is an integer of 1 to 3. When c is 2 or more, a plurality of Res are the same or different from each other.

Examples of the alkyl group having 1 to 10 carbon atoms represented by R² include a methyl group, an ethyl group, a n-propyl group, an i-propyl group, a n-butyl group, an i-butyl group, a t-butyl group and the like.

The substituents of the alkyl group include halogen atoms such as a fluorine atom, a chlorine atom, a bromine atom, and an iodine atom. The alkyl group having 1 to 10 carbon atoms represented by R² is preferably unsubstituted.

The c is preferably 1 or 2, more preferably 1.

The lower limit of the content of the second structural unit in all structural units constituting the second polysiloxane is preferably 10 mol %, more preferably 15 mol %, and even more preferably 20 mol %. The upper limit of the content is preferably 100 mol %, more preferably 95 mol %, even more preferably 90 mol %, and particularly preferably 85 mol %. By setting the content of the second structural unit in the second polysiloxane within the above range, the silicon-containing film formed by the silicon-containing composition can impart excellent cross-sectional rectangularity to the resist pattern.

### (Third Structural Unit)

The second polysiloxane may have, as a structural unit other than the second structural unit, the above-described third structural unit shown as an additional structural unit in the first polysiloxane. By having the third structural unit, it is possible to exhibit an antireflection performance on the resist film during exposure and form a resist pattern having excellent cross-sectional rectangularity.

When the second polysiloxane has the third structural unit, the lower limit of the content of the third structural unit in all the structural units constituting the second polysiloxane is preferably 5 mol %, more preferably 10 mol %, and even more preferably 15 mol %. The upper limit of the content of the third structural unit is preferably 50 mol %, more preferably 45 mol %, and even more preferably 40 mol %. When the content of the third structural unit is within the above range, a silicon-containing film having more excellent antireflection performance can be formed.

(Fourth structural unit)

The second polysiloxane may have, as a structural unit other than the second structural unit, the fourth structural unit shown as an additional structural unit in the first polysiloxane. When the second polysiloxane has the fourth structural unit, the oxygen gas etching resistance of the silicon-containing film formed from the silicon-containing composition can be improved.

When the second polysiloxane contains the fourth structural unit, the lower limit of the content of the fourth structural unit in all structural units constituting the second polysiloxane is preferably 10 mol %, more preferably 15 mol %, and even more preferably 20 mol %. The upper limit of the content of the fourth structural unit is preferably 90 mol %, more preferably 80 mol %, and even more preferably 70 mol %.

The lower limit of the content of the second polysiloxane in the total mass of the first polysiloxane and the second polysiloxane is preferably 1% by mass, more preferably 2% by mass, and even more preferably 5% by mass. The upper limit of the content is preferably 60% by mass, more preferably 50% by mass, and even more preferably 40% by mass. Thereby, pattern rectangularity can be improved while maintaining film removability.

The lower limit of the total content of the two types of polysiloxanes (specific polysiloxanes) in the silicon-containing composition is preferably 0.1% by mass, more preferably 0.5% by mass, and even more preferably 1% by mass based on all components contained in the silicon-containing composition. The upper limit of the content is preferably 10% by mass, more preferably 7.5% by mass, and even more preferably 5% by mass.

The specific polysiloxanes are preferably in the form of a polymer. As used herein, the term “polymer” refers to a compound having two or more structural units, and when two or more identical structural units are consecutive in a polymer, the structural units are also referred to as “repeating units”. When the specific polysiloxanes are in the form of a polymer, the lower limit of the polystyrene-equivalent weight average molecular weight (Mw) of the specific polysiloxanes by gel permeation chromatography (GPC) is preferably 1,000, more preferably 1,100, even more preferably 1,200, and particularly preferably 1,500. The upper limit of Mw is preferably 8,000, more preferably 5,000, still more preferably 3,000, and particularly preferably 2,500.

As used herein, the Mws of the specific polysiloxanes are a value measured by gel permeation chromatography (GPC) using GPC columns, available from Tosoh Corporation

(“G2000HXL” x 2, “G3000HXL” x 1, and “G4000HXL” x 1) under the following conditions.

Eluant: tetrahydrofuran

Flow rate: 1.0 mL/min

Sample concentration: 1.0% by mass

Sample injection amount: 100 μL

Column temperature: 40° C.

Detector: differential refractometer

Standard substance: monodisperse polystyrene

[Method for synthesizing polysiloxane]

The specific polysiloxanes can be synthesized by a conventional method using monomers that provide each structural unit. For example, in the first polysiloxane, a monomer that provides the first structural unit and optionally a monomer that provides other structural units can be hydrolyzed and condensed in a solvent in the presence of a catalyst such as oxalic acid and water, and preferably a solution containing the produced hydrolytic condensate can be purified by performing solvent substitution or the like in the presence of a dehydrating agent such as trimethyl orthoformate to synthesize the specific polysiloxanes. It is believed that each monomer is incorporated into the first polysiloxane by hydrolytic condensation reaction or the like regardless of its type. Therefore, each content of the first structural unit and the other structural units in the synthesized first polysiloxane is usually equal to the ratio of the charged amount of each monomer used in the synthesis reaction. The second polysiloxane can also be synthesized by hydrolyzing and condensing a monomer that provides the second structural unit and, if necessary, a monomer that provides another structural unit in the same manner as described above.

### [Solvent]

The solvent is not particularly limited, and examples thereof include alcohol-based solvents, ketone-based solvents, ether-based solvents, ester-based solvents, nitrogen-containing solvents, and water. The silicon-containing composition may contain one or more [B]solvents.

Examples of alcohol solvents include monoalcohol solvents such as methanol, ethanol, n-propanol, iso-propanol, n-butanol and iso-butanol, polyhydric alcohol solvents such as ethylene glycol, 1,2-propylene glycol, diethylene glycol and dipropylene glycol.

Examples of ketone solvents include acetone, methyl ethyl ketone, methyl-n-propyl ketone, methyl-iso-butyl ketone, cyclohexanone and the like.

Examples of ether solvents include ethyl ether, iso-propyl ether, ethylene glycol dibutyl ether, diethylene glycol monomethyl ether, diethylene glycol monoethyl ether, diethylene glycol diethyl ether, propylene glycol monomethyl ether, propylene glycol monoethyl ether, propylene glycol monopropyl ether, tetrahydrofuran and the like.

Examples of ester solvents include ethyl acetate, y-butyrolactone, n-butyl acetate, ethylene glycol monomethyl ether acetate, ethylene glycol monoethyl ether acetate, diethylene glycol monomethyl ether acetate, diethylene glycol monoethyl ether acetate, propylene glycol monomethyl ether acetate, propylene glycol monoethyl ether acetate, dipropylene glycol monomethyl ether acetate, dipropylene glycol monoethyl ether acetate, ethyl propionate, n-butyl propionate, methyl lactate, ethyl lactate and the like.

Examples of nitrogen-containing solvents include N,N-dimethylformamide, N,N-dimethylacetamide, N-methylpyrrolidone, and the like.

Among these, ether-based solvents or ester-based solvents are preferable, and ether-based solvents or ester-based solvents having a glycol structure are more preferable because of their excellent film-forming properties.

Examples of ether solvents and ester solvents having a glycol structure include propylene glycol monomethyl ether, propylene glycol monoethyl ether, propylene glycol monopropyl ether, propylene glycol monomethyl ether acetate, propylene glycol monoethyl ether acetate, and propylene glycol monopropyl ether acetate and the like. Among these, propylene glycol monomethyl ether acetate or propylene glycol monoethyl ether is preferable, and propylene glycol monoethyl ether is more preferable.

The lower limit of the content of the solvent in the silicon-containing composition is preferably 90% by mass, more preferably 92.5% by mass, and even more preferably 95% by mass, relative to all components contained in the silicon-containing composition. The upper limit of the content is preferably 99.9% by mass, more preferably 99.5% by mass, and even more preferably 99% by mass.

### (Optional Component)

Examples of optional components include acid generators, basic compounds (including base generators), radical generators, surfactants, colloidal silica, colloidal alumina, and organic polymers. The silicon-containing composition can contain one or more optional components.

When the silicon-containing composition contains optional components, the content of the optional component in the silicon-containing composition can be appropriately determined according to the type of the optional components used and within a range that does not impair the effects of the present invention.

### <Method for Preparing Silicon-Containing Composition>

The method for preparing the silicon-containing composition is not particularly limited, and it can be prepared according to a conventional method. For example, a solution of the specific polysiloxanes, a solvent, and optionally optional components are mixed in a predetermined ratio, and the resulting mixed solution is preferably filtered through a filter having a pore size of 0.2 μm or less to prepare the silicon-containing composition.

### <Method for Manufacturing Semiconductor Substrate>

A method for manufacturing a semiconductor substrate according to the present embodiment includes: directly or indirectly applying a silicon-containing composition to a substrate to form a silicon-containing film (hereinafter, also referred to as a “silicon-containing film forming step”); directly or indirectly applying a composition for forming a resist film to the silicon-containing film to form the resist film (hereinafter, also referred to as a “resist film forming step”); exposing the resist film to radiation (hereinafter, also referred to as an “exposing step”); developing the exposed resist film to form a resist pattern (hereinafter, also referred to as a “developing step”); etching the silicon-containing film using the resist pattern as a mask to form a silicon-containing film pattern (hereinafter, also referred to as a “silicon-containing film pattern forming step”); performing etching using the silicon-containing film pattern as a mask (hereinafter, an “etching step”); and removing the silicon-containing film pattern by a basic liquid (hereinafter, a “removing step”). In the silicon-containing film forming step in the method for manufacturing a semiconductor substrate, the above-described silicon-containing composition is used as the silicon-containing composition.

The method for manufacturing a semiconductor substrate may further include, if necessary, directly or indirectly forming an organic underlayer film on the substrate (hereinafter, also referred to as an “organic underlayer film forming step”) before the silicon-containing film forming step.

According to the method for manufacturing a semiconductor substrate, by using the above-described silicon-containing composition as the silicon-containing composition in the silicon-containing film forming step, the resist pattern having excellent cross-sectional shape rectangularity can be formed on the silicon-containing film. The silicon-containing film formed in the silicon-containing film forming step has excellent film removability, and thus can be removed by a basic liquid.

Each step included in the method for manufacturing a semiconductor substrate will be described below.

[Silicon-containing film forming step]

In this step, the silicon-containing composition is directly or indirectly applied to the substrate to form a silicon-containing film. By this step, a coating film of the silicon-containing composition is formed directly or indirectly on the substrate, and the coating film is usually cured by heating to form a silicon-containing film.

In this step, the silicon-containing composition described above is used as the silicon-containing composition.

Examples of substrates include insulating films such as silicon oxide, silicon nitride, silicon oxynitride and polysiloxane, and resin substrates. Also, the substrate may be a substrate having patterning such as a wiring groove (trench), a plug groove (vias) and the like.

The method of applying the silicon-containing composition is not particularly limited, and examples thereof include a spin coating method.

Examples of the case of indirectly applying the silicon-containing composition to the substrate include, for example, the case of applying the silicon-containing composition onto another film formed on the substrate. Other films formed on the substrate include, for example, an organic underlayer film which is formed by the organic underlayer film forming step described later, an antireflection film, a low dielectric insulating film, and the like.

When the coating film is heated, the atmosphere is not particularly limited, and examples thereof include air atmosphere, nitrogen atmosphere, and the like. Heating of the coating film is usually performed in the air atmosphere. Various conditions such as the heating temperature and the heating time when the coating film is heated can be appropriately determined. The lower limit of the heating temperature is preferably 90° C., more preferably 150° C., and even more preferably 200° C. The upper limit of the heating temperature is preferably 550° C., more preferably 450° C., and even more preferably 300° C. The lower limit of the heating time is preferably 15 seconds, more preferably 30 seconds. The upper limit of the heating time is preferably 1,200 seconds, more preferably 600 seconds.

When the composition for forming a silicon-containing film contains an acid generator, and the acid generator is a radiation-sensitive acid generator, the formation of the silicon-containing film can be accelerated by combining heating and exposure. Radiation used for exposure includes, for example, the same radiation as exemplified in the exposing step described later.

The lower limit of the average thickness of the silicon-containing film formed by this step is preferably 1 nm, more preferably 3 nm, and even more preferably 5 nm. The upper limit of the average thickness is preferably 500 nm, more preferably 300 nm, and even more preferably 200 nm. The method for measuring the average thickness of the silicon-containing film is described in Examples.

### [Resist Film Forming Step]

In this step, a composition for forming a resist film is directly or indirectly applied to the silicon-containing film to form the resist film. Through this step, a resist film is formed directly or indirectly on the silicon-containing film.

The method of applying the composition for forming a resist film is not particularly limited, and examples thereof include a spin coating method.

To explain this step in more detail, for example, after applying a resist composition so that the formed resist film has a predetermined thickness, pre-baking (hereinafter also referred to as “PB”) is performed to volatilize the solvent to form a resist film.

The PB temperature and PB time can be appropriately determined according to the type of resist film forming composition used. The lower limit of the PB temperature is preferably 30° C., more preferably 50° C. The upper limit of the PB temperature is preferably 200° C., more preferably 150° C. The lower limit of the PB time is preferably 10 seconds, more preferably 30 seconds. The upper limit of the PB time is preferably 600 seconds, more preferably 300 seconds.

As the composition for forming a resist film used in this step, a known composition for forming a resist film can be used regardless of whether it is a so-called positive type for alkali development or a so-called negative type for organic solvent development. In the silicon-containing film formed as described above, the second polysiloxane having a hydrophobic group is unevenly distributed on the surface side, and is durable to an alkaline solution for alkaline development, making it possible to form a desired resist pattern even with a positive type composition for forming a resist film. Such a composition for forming a resist film preferably includes, for example, a positive type composition for forming a resist film containing a resin having an acid-dissociable group and a radiation-sensitive acid generator, and for exposure with ArF excimer laser light (for ArF exposure) described later.

### [Exposing Step]

In this step, the resist film formed by the resist film forming step is exposed to radiation. This step causes a difference in solubility in an alkaline solution, which is a developer, between an exposed portion and an unexposed portion of the resist film. More specifically, the solubility of the exposed portion of the resist film to an alkaline solution increases.

The radiation used for exposure can be appropriately selected according to the type of a composition for forming a resist film used. Examples thereof include electromagnetic waves such as visible light, ultraviolet rays, far ultraviolet rays, X-rays and y-rays, and particle beams such as electron beams, molecular beams and ion beams. Among these, far ultraviolet rays are preferable, and KrF excimer laser light (wavelength 248 nm), ArF excimer laser light (wavelength 193 nm), F2 excimer laser light (wavelength 157 nm), Kr2 excimer laser light (wavelength 147 nm), ArKr excimer laser light (wavelength of 134 nm) or extreme ultraviolet rays (wavelength of 13.5 nm, etc., also referred to as “EUV”) are more preferred, and ArF excimer laser light or EUV is even more preferred. Also, the exposure conditions can be appropriately determined according to the type of the composition for forming a resist film to be used.

In addition, in this step, post-exposure bake (hereinafter also referred to as “PEB”) can be performed in order to improve the performance of the resist film such as resolution, pattern profile, developability, etc. after the exposure. The PEB temperature and PEB time can be appropriately determined according to the type of composition for forming a resist film used. The lower limit of the PEB temperature is preferably 50° C., more preferably 70° C. The upper limit of the PEB temperature is preferably 200° C., more preferably 150° C. The lower limit of the PEB time is preferably 10 seconds, more preferably 30 seconds. The upper limit of the PEB time is preferably 600 seconds, more preferably 300 seconds.

### [Developing Step]

In this step, the exposed resist film is developed. Due to the above exposing step, the solubility in the alkaline solution, which is the developer, differs between the exposed area and the unexposed area in the resist film. A resist pattern is formed by removing the exposed portion, which is relatively soluble in an alkaline solution, by carrying out alkali development.

The developer used in alkaline development is not particularly limited, and known developers can be used. Examples of developer for alkaline development include an alkaline aqueous solution containing at least one of dissolved alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, 1,5-diazabicyclo-[4.3.0]-5-nonene, and the like. Among these, a TMAH aqueous solution is preferable, and a 2.38% by mass TMAH aqueous solution is more preferable.

Examples of a developer used for organic solvent development include the same developer as those exemplified as the solvent for the silicon-containing composition described above.

In this step, washing and/or drying may be performed after the development.

### [Silicon-Containing Film Pattern Forming Step]

In this step, the silicon-containing film is etched using the resist pattern as a mask to form a silicon-containing film pattern.

The above etching may be dry etching or wet etching, but dry etching is preferred.

Dry etching can be performed using, for example, a known dry etching apparatus. The etching gas used for dry etching can be appropriately selected according to the elemental composition of the silicon-containing film to be etched, and for example, fluorine-based gases such as CHF₃, CF₄, C₂F₆, C₃F₈ and SF₆, chlorine-based gases such as Cl₂ and BCl₃, oxygen-based gases such as 02, 03 and H20, reducing gases such as H2, CO, CO₂, CH₄, C₂H₂, C₂H₄, C₂H₆, C₃H₄, C₃H₆, C₃H₈, HF, HI, HBr, HCl, NO and NH₃, and inert gases such as He, N₂ and Ar are used. These gases can also be mixed and used. For dry etching of a silicon-containing film, a fluorine-based gas is usually used, and a mixture of a fluorine-based gas, an oxygen-based gas and an inert gas is preferably used.

### [Etching Step]

In this step, etching is performed using the silicon-containing film pattern as a mask. More specifically, etching is performed one or more times using as a mask the pattern formed in the silicon-containing film obtained in the silicon-containing film pattern forming step to obtain a patterned substrate.

When an organic underlayer film is formed on the substrate, the organic underlayer film is etched using the silicon-containing film pattern as a mask to form a pattern of the organic underlayer film, and then the substrate is etched using this organic underlayer film pattern as a mask. Thus, a pattern is formed on the substrate.

The above etching may be dry etching or wet etching, but dry etching is preferred.

Dry etching for forming a pattern on the organic underlayer film can be performed using a known dry etching apparatus. The etching gas used for dry etching can be appropriately selected depending on the elemental composition of the silicon-containing film and the organic underlayer film to be etched. As the etching gas, the gas for etching the silicon-containing film described above can be suitably used, and these gases can also be mixed and used. An oxygen-based gas is usually used for dry etching of the organic underlayer film using the silicon-containing film pattern as a mask.

Dry etching for forming a pattern on the substrate using the organic underlayer film pattern as a mask can be performed using a known dry etching apparatus. The etching gas used for dry etching can be appropriately selected depending on the elemental composition of the organic underlayer film and the substrate to be etched, and the like. For example, etching gases similar to those exemplified as the etching gas used for the dry etching of the organic underlayer film may be used.

Etching may be performed a plurality of times with different etching gases. After the etching step, if the silicon-containing film remains on the substrate, or on the organic underlayer film pattern, etc., the silicon-containing film can be removed by performing the removing step described below.

### [Removing Step]

In this step, the silicon-containing film pattern is removed with a basic liquid. This step removes the silicon-containing film from the substrate. Also, the silicon-containing film residue after etching can be removed.

The basic liquid is not particularly limited as long as it is a basic solution containing a basic compound. Examples of basic compounds include sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide (hereinafter also referred to as “TMAH”), tetraethylammonium hydroxide, pyrrole, piperidine, choline, 1,8-diazabicyclo[5.4.0]-7-undecene, 1,5-diazabicyclo[4.3.0]-5-nonene and the like. Among these, ammonia is preferable from the viewpoint of avoiding damage to the substrate.

From the viewpoint of further improving the removability of the silicon-containing film, the basic liquid is preferably a liquid containing a basic compound and water, or a liquid containing a basic compound, hydrogen peroxide and water.

The method for removing the silicon-containing film is not particularly limited as long as it is a method that allows the silicon-containing film and the basic liquid to come into contact with each other. Examples thereof include a method of immersing a substrate in a basic liquid, a method of spraying a basic liquid, a method of applying a basic liquid, and the like.

The temperature, time, and other conditions for removing the silicon-containing film are not particularly limited, and can be appropriately determined according to the film thickness of the silicon-containing film, the type of basic liquid used, and the like. The lower limit of the temperature is preferably 20° C., more preferably 40° C., and even more preferably 50° C. The upper limit of the temperature is preferably 300° C., more preferably 100° C. The lower limit of the time is preferably 5 seconds, more preferably 30 seconds. The upper limit of the time is preferably 10 minutes, more preferably 180 seconds.

In this step, washing and/or drying may be performed after removing the silicon-containing film.

### [Organic Underlayer Film Forming Step]

In this step, an organic underlayer film is formed directly or indirectly on the substrate before the silicon-containing film forming step. This step is an arbitrary step. Through this step, an organic underlayer film is formed directly or indirectly on the substrate.

The organic underlayer film can be formed by coating a composition for forming an organic underlayer film. The method of forming the organic underlayer film by coating the composition for forming an organic underlayer film includes, for example, a method in which a coating film formed by directly or indirectly coating the composition for forming an organic underlayer film on a substrate is cured by heating or exposing. As the composition for forming the organic underlayer film, for example, “HM8006” manufactured by JSR Corporation can be used. Various conditions for heating and exposure can be appropriately determined according to the type of the composition for forming an organic underlayer film to be used.

A case of forming an organic underlayer film indirectly on a substrate includes, for example, a case of forming an organic underlayer film on a low dielectric insulating film formed on a substrate.

### EXAMPLES

Hereinafter, Examples are described. The following Examples merely illustrate typical Examples of the present invention, and the Examples should not be construed to narrow the scope of the present invention.

In the present Examples, the weight average molecular weight (Mw) of each of two types of polysiloxanes, the concentration of the polysiloxane in a solution, and the average thickness of a film were measured by the following methods.

### [Measurement of Weight Average Molecular Weight (Mw)]

The weight average molecular weight (Mw) of the polysiloxane was measured by gel permeation chromatography (GPC) using GPC columns, available from Tosoh Corporation (“G2000HXL” x 2, “G3000HXL” x 1, and “G4000HXL” x 1) under the following conditions.
(Measurement conditions)
Eluant: tetrahydrofuran
Flow rate: 1.0 mL/min
Sample concentration: 1.0% by mass
Sample injection amount: 100 pL
Column temperature: 40° C.
Detector: differential refractometer
Standard substance: monodisperse polystyrene

### [Concentration of Polysiloxane in Solution]

The concentration (unit: % by mass) of the solution of the polysiloxane was calculated by firing 0.5 g of the solution of the polysiloxane at 250° C. for 30 minutes, measuring a mass of a residue thus obtained, and dividing the mass of the residue by the mass of the solution of the polysiloxane.

### [Average Thickness of Film]

The average thickness of the film was measured by using a spectroscopic ellipsometer (“M2000D”, available from J. A. WOOLLAM Company). More specifically, thicknesses of the film were measured at optional nine points located at an interval of 5 cm including the center of the film, and the average value of the film thicknesses was calculated, and taken as the average thickness.

### <Synthesis of First Polysiloxane>

Monomers (hereinafter, also referred to as “monomers (M-1) to (M-15)”) used for synthesis in Synthesis Example 1-1 to Synthesis Example 1-23 are shown below. In the following Synthesis Example 1-1 to Synthesis Example 1-23, mol % means a value for each monomer when the total number of moles of the monomers (M-1) to (M-15) used is 100 mol %.

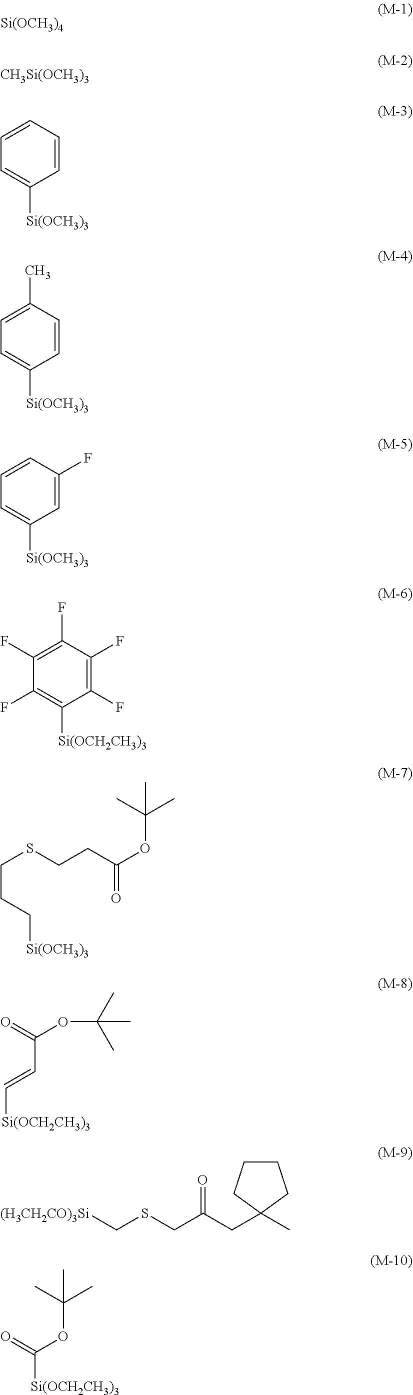

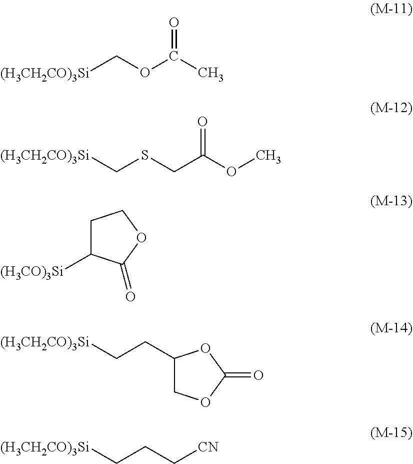

### [Synthesis Example 1-1] Synthesis of First Polysiloxane (A-1)

In a reaction vessel, the compound (M-1), the compound (M-5), and the compound (M-7) were dissolved in 62 parts by mass of propylene glycol monoethyl ether so that the molar ratio of the compounds was 84/15/1 (mol %) to prepare a monomer solution. A temperature in the reaction vessel was set to 60° C., and 40 parts by mass of a 9.1% by mass oxalic acid aqueous solution was added dropwise thereto over 20 minutes with stirring. The reaction was performed for 4 hours with the start of the dropwise addition as the start time of the reaction. After the completion of the reaction, the inside of the reaction vessel was cooled to 30° C. or lower. After 550 parts by mass of propylene glycol monoethyl ether was added to the cooled reaction solution, water, alcohols produced by the reaction, and excessive propylene glycol monoethyl ether were removed using an evaporator to obtain a propylene glycol monoethyl ether solution of a first polysiloxane (A-1). The Mw of the first polysiloxane (A-1) was 1,700. The concentration of the first polysiloxane (A-1) in the propylene glycol monoethyl ether solution was 7.2% by mass.

[Synthesis Example 1-2 to Synthesis Example 1-23] Synthesis of first polysiloxanes (A-2) to (A-23)

Propylene glycol monoethyl ether solutions of the first polysiloxanes (A-2) to (A-23) were obtained in the same manner as in Synthesis Example 1-1 except that the types and amounts of monomers shown in the following Table 1 were used. In the following Table 1, “-” in the monomers indicates that the corresponding monomer was not used. The Mw of the obtained first polysiloxane and the concentration (% by mass) of the first polysiloxane in the solution are also shown in the following Table 1.

TABLE 1

| | | Charged amount of each monomer (mol %) | | | | | | | | |
|---|---|---|---|---|---|---|---|---|---|---|
| | | Fourth | Second | | | | | | | |
| | | structural | structural | | | | | | | |
| | First | unit | unit | Third structural unit | | | | First structural unit | | |
| | polysiloxane | M-1 | M-2 | M-3 | M-4 | M-5 | M-6 | M-7 | M-8 | M-9 |
| Synthesis | A-1 | 84 | — | — | — | 15 | — | 1 | — | — |
| Example 1-1 | | | | | | | | | | |
| Synthesis | A-2 | 83 | — | — | — | 15 | — | 2 | — | — |
| Example 1-2 | | | | | | | | | | |
| Synthesis | A-3 | 80 | — | — | — | 15 | — | 5 | — | — |
| Example 1-3 | | | | | | | | | | |
| Synthesis | A-4 | 75 | — | — | — | 20 | — | 5 | — | — |
| Example 1-4 | | | | | | | | | | |
| Synthesis | A-5 | 70 | — | — | — | 25 | — | 5 | — | — |
| Example 1-5 | | | | | | | | | | |
| Synthesis | A-6 | 65 | — | — | — | 30 | — | 5 | — | — |
| Example 1-6 | | | | | | | | | | |
| Synthesis | A-7 | 60 | — | — | — | 35 | — | 5 | — | — |
| Example 1-7 | | | | | | | | | | |
| Synthesis | A-8 | 65 | — | — | — | 25 | — | 10 | — | — |
| Example 1-8 | | | | | | | | | | |
| Synthesis | A-9 | 55 | — | — | — | 25 | — | 20 | — | — |
| Example 1-9 | | | | | | | | | | |
| Synthesis | A-10 | 50 | — | — | — | 25 | — | 25 | — | — |
| Example 1-10 | | | | | | | | | | |
| Synthesis | A-11 | 80 | — | — | — | 15 | — | — | 5 | — |
| Example 1-11 | | | | | | | | | | |
| Synthesis | A-12 | 70 | — | — | — | 25 | — | — | — | 5 |
| Example 1-12 | | | | | | | | | | |
| Synthesis | A-13 | 80 | — | — | — | 15 | — | — | — | — |
| Example 1-13 | | | | | | | | | | |
| Synthesis | A-14 | 80 | — | — | — | 15 | — | — | — | — |
| Example 1-14 | | | | | | | | | | |
| Synthesis | A-15 | 70 | — | — | — | 25 | — | — | — | — |
| Example 1-15 | | | | | | | | | | |
| Synthesis | A-16 | 80 | — | — | — | 15 | — | — | — | — |
| Example 1-16 | | | | | | | | | | |
| Synthesis | A-17 | 80 | — | — | — | 15 | — | — | — | — |
| Example 1-17 | | | | | | | | | | |
| Synthesis | A-18 | 80 | — | — | — | 15 | — | — | — | — |
| Example 1-18 | | | | | | | | | | |
| Synthesis | A-19 | 70 | 5 | — | — | — | 20 | 5 | — | — |
| Example 1-19 | | | | | | | | | | |
| Synthesis | A-20 | 80 | — | 15 | — | — | — | 5 | — | — |
| Example 1-20 | | | | | | | | | | |
| Synthesis | A-21 | 75 | — | 15 | 5 | — | — | 5 | — | — |
| Example 1-21 | | | | | | | | | | |
| Synthesis | A-22 | 75 | — | 15 | — | 5 | — | 5 | — | — |
| Example 1-22 | | | | | | | | | | |
| Synthesis | A-23 | 90 | — | — | — | — | — | 10 | — | — |
| Example 1-23 | | | | | | | | | | |
| | | | Charged amount of each monomer (mol %) | | | | | | | Concentration |
| | | | First structural unit | | | | | | | in solution |
| | | | M-10 | M-11 | M-12 | M-13 | M-14 | M-15 | Mw | (% by mass) |
| | | Synthesis | — | — | — | — | — | — | 1,700 | 7.2 |
| | | Example 1-1 | | | | | | | | |
| | | Synthesis | — | — | — | — | — | — | 1,700 | 7.1 |
| | | Example 1-2 | | | | | | | | |
| | | Synthesis | — | — | — | — | — | — | 1,710 | 7.2 |
| | | Example 1-3 | | | | | | | | |
| | | Synthesis | — | — | — | — | — | — | 1,720 | 7.4 |
| | | Example 1-4 | | | | | | | | |
| | | Synthesis | — | — | — | — | — | — | 1,600 | 7.3 |
| | | Example 1-5 | | | | | | | | |
| | | Synthesis | — | — | — | — | — | — | 1,630 | 7.3 |
| | | Example 1-6 | | | | | | | | |
| | | Synthesis | — | — | — | — | — | — | 1,670 | 7.0 |
| | | Example 1-7 | | | | | | | | |
| | | Synthesis | — | — | — | — | — | — | 1,800 | 6.6 |
| | | Example 1-8 | | | | | | | | |
| | | Synthesis | — | — | — | — | — | — | 1,520 | 6.9 |
| | | Example 1-9 | | | | | | | | |
| | | Synthesis | — | — | — | — | — | — | 1,510 | 6.9 |
| | | Example 1-10 | | | | | | | | |
| | | Synthesis | — | — | — | — | — | — | 2,000 | 7.5 |
| | | Example 1-11 | | | | | | | | |
| | | Synthesis | — | — | — | — | — | — | 1,600 | 7.0 |
| | | Example 1-12 | | | | | | | | |
| | | Synthesis | 5 | — | — | — | — | — | 1,750 | 7.1 |
| | | Example 1-13 | | | | | | | | |
| | | Synthesis | — | 5 | — | — | — | — | 1,550 | 6.6 |
| | | Example 1-14 | | | | | | | | |
| | | Synthesis | — | — | 5 | — | — | — | 1,860 | 7.3 |
| | | Example 1-15 | | | | | | | | |
| | | Synthesis | — | — | — | 5 | — | — | 1,510 | 7.2 |
| | | Example 1-16 | | | | | | | | |
| | | Synthesis | — | — | — | — | 5 | — | 1,940 | 7.8 |
| | | Example 1-17 | | | | | | | | |
| | | Synthesis | — | — | — | — | — | 5 | 1,860 | 7.4 |
| | | Example 1-18 | | | | | | | | |
| | | Synthesis | — | — | — | — | — | — | 1,680 | 7.4 |
| | | Example 1-19 | | | | | | | | |
| | | Synthesis | — | — | — | — | — | — | 1,600 | 7.0 |
| | | Example 1-20 | | | | | | | | |
| | | Synthesis | — | — | — | — | — | — | 1,650 | 7.1 |
| | | Example 1-21 | | | | | | | | |
| | | Synthesis | — | — | — | — | — | — | 1,720 | 6.9 |
| | | Example 1-22 | | | | | | | | |
| | | Synthesis | — | — | — | — | — | — | 1,850 | 7.0 |
| | | Example 1-23 | | | | | | | | |

[Synthesis Example 2-1] Synthesis of second polysiloxane (B-1)

In a reaction vessel, the compound (M-1) and the compound (M-2) were dissolved in 62 parts by mass of propylene glycol monoethyl ether so that the molar ratio of the compounds was 50/50 (mol %) to prepare a monomer solution. A temperature in the reaction vessel was set to 60° C., and 40 parts by mass of a 9.1% by mass oxalic acid aqueous solution was added dropwise thereto over 20 minutes with stirring. The reaction was performed for 4 hours with the start of the dropwise addition as the start time of the reaction. After the completion of the reaction, the inside of the reaction vessel was cooled to 30° C. or lower. After 550 parts by mass of propylene glycol monoethyl ether was added to the cooled reaction solution, water, alcohols produced by the reaction, and excessive propylene glycol monoethyl ether were removed using an evaporator to obtain a propylene glycol monoethyl ether solution of a second polysiloxane (B-1). The Mw of the second polysiloxane (B-1) was 1,900. The concentration of the second polysiloxane (B-1) in the propylene glycol monoethyl ether solution was 7.1% by mass.

[Synthesis Example 2-2 to Synthesis Example 2-10] Synthesis of second polysiloxanes (B-2) to (B-10)

Propylene glycol monoethyl ether solutions of second polysiloxanes (B-2) to (B-10) were obtained in the same manner as in Synthesis Example 2-1 except that the types and amounts of monomers shown in the following Table 2 were used. In the following Table 2, “-” in the monomers indicates that the corresponding monomer was not used. The Mw of the obtained second polysiloxane and the concentration (% by mass) of the second polysiloxane in the solution are also shown in the following Table 2.

TABLE 2

| | | Charged amount of each monomer (mol %) | | | | | | | |
|---|---|---|---|---|---|---|---|---|---|
| | | Fourth | Second | | | | | | Concentration |
| | Second, | structural unit | structural unit | Third structural unit | | | | | in solution |
| | polysiloxane | M-1 | M-2 | M-3 | M-4 | M-5 | M- 6 | Mw | (% by mass) |
| Synthesis | B-1 | 50 | 50 | — | — | — | — | 1,900 | 7.1 |
| Example 2-1 | | | | | | | | | |
| Synthesis | B-2 | 40 | 60 | — | — | — | — | 1,920 | 7.0 |
| Example 2-2 | | | | | | | | | |
| Synthesis | B-3 | 30 | 70 | — | — | — | — | 1,980 | 7.4 |
| Example 2-3 | | | | | | | | | |
| Synthesis | B-4 | 20 | 80 | — | — | — | — | 1,960 | 6.8 |
| Example 2-4 | | | | | | | | | |
| Synthesis | B-5 | — | 100 | — | — | — | — | 1,930 | 6.9 |
| Example 2-5 | | | | | | | | | |
| Synthesis | B-6 | 70 | 30 | — | — | — | — | 1,900 | 7.5 |
| Example 2-6 | | | | | | | | | |
| Synthesis | B-7 | 60 | 40 | — | — | — | — | 2,000 | 7.5 |
| Example 2-7 | | | | | | | | | |
| Synthesis | B-8 | 60 | — | 40 | — | — | — | 1,830 | 6.9 |
| Example 2-8 | | | | | | | | | |
| Synthesis | B-9 | 60 | 20 | 20 | — | — | — | 1,820 | 6.7 |
| Example 2-9 | | | | | | | | | |
| Synthesis | B-10 | 60 | — | — | — | 40 | — | 1,750 | 6.9 |
| Example 2-10 | | | | | | | | | |

<Preparation of Silicon-Containing Composition>

A solvent used for preparing the silicon-containing composition is shown below. In the following Examples 1 to 38 and Comparative Examples 1 and 2, unless otherwise specified, parts by mass represents a value when the total mass of components used is 10,000 parts by mass.

### [Solvent]

C-1: Propylene glycol monoethyl ether

[Example 1] Preparation of silicon-containing composition for ArF exposure (J-1)

90 parts by mass of a first polysiloxane (A-1), 10 parts by mass of a second polysiloxane (B-1), and 9900 parts by mass of a solvent (C-1) (solvents contained in a solution of two types of polysiloxanes were also included) were mixed, and the obtained solution was filtered through a polytetrafluoroethylene filter having a pore size of 0.2 pm to prepare a silicon-containing composition for ArF exposure (J-1).

[Examples 2 to 37 and Comparative Examples 1 and 2] Preparation of Silicon-Containing Compositions for ArF Exposure (J-2) to (J-37), (j-1), and (j-2)

Silicon-containing compositions for ArF exposure (J-2) to (J-37) of Examples 2 to 37 and silicon-containing compositions for ArF exposure (j-1) and (j-2) of Comparative

Examples 1 and 2 were prepared in the same manner as in Example 1 except that respective components of types and blending amounts shown in the following Table 2 were used.

Example 38] Preparation of silicon-containing composition for EUV exposure (J-38)

90 parts by mass of a first polysiloxane (A-23), 10 parts by mass of a second polysiloxane (B-1), and 9900 parts by mass of a solvent (C-1) (solvents contained in a solution of two types of polysiloxanes were also included) were mixed, and the obtained solution was filtered through a polytetrafluoroethylene filter having a pore size of 0.2 μm to prepare a silicon-containing composition for EUV exposure (J-38).

<Evaluation>

Using the compositions prepared as described above, pattern rectangularity and film removability were evaluated by the following method. The evaluation results are shown in the following Table 3.

### [Pattern Rectangularity (ArF Immersion Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Limited), and thereafter heating was conducted at 250° C. for 60 sec to form an organic underlayer film having an average thickness of 100 nm. Each silicon-containing composition for ArF exposure prepared as described above was applied on the organic underlayer film, and subjected to heating at 220° C. for 60 sec, followed by cooling at 23° C. for 30 sec to form a silicon-containing film having an average thickness of 20 nm. A radiation-sensitive resin composition (“ARF AR2772JN”, available from JSR Corporation) was applied on each silicon-containing film formed as described above, and heating was conducted at 90° C. for 60 sec, followed by cooling at 23° C. for 30 sec to form a resist film having an average thickness of 100 nm. Then, using an ArF immersion exposure apparatus (“S610C”, available from NIKON), the substrate was exposed through a mask having a mask size for 40 nm line/80 nm pitch formation under optical conditions of NA: 1.30 and Dipole, then heated at 100° C. for 60 sec, followed by cooling at 23° C. for 60 sec. Thereafter, development was performed by a paddle method using a 2.38% by mass aqueous TMAH solution (20° C. to 25° C.), followed by washing with water and drying, thereby obtaining a substrate for evaluation having a resist pattern formed thereon. A scanning electron microscope (“CG-4000”, available from Hitachi High-Technologies Corporation) was used for measuring the length of the resist pattern of the substrate for evaluation and observing the cross-sectional shape of the resist pattern. In the substrate for evaluation, an exposure amount at which a 1: 1 line and space pattern with a line width of 40 nm was formed was defined as an optimum exposure amount. The pattern rectangularity was evaluated as “A” (good) when the cross-sectional shape of the pattern was rectangular, “B” (slightly good) when trailing was present in the cross section of the pattern, and “C” (poor) when a residue (defect) was present in the pattern.

<Preparation of Resist Composition for EUV Exposure>

A resist composition for EUV exposure (R-1) was obtained by mixing 100 parts by mass of a polymer having a structural unit (1) derived from 4-hydroxystyrene, a structural unit (2) derived from styrene, and a structural unit (3) derived from 4-t-butoxystyrene (content of each structural unit contained:

(1)/(2)/(3)=65/5/30 (mol %)), 1.0 parts by mass of triphenylsulfonium trifluoromethanesulfonate as a radiation-sensitive acid generating agent, and 4,400 parts by mass of ethyl lactate and 1,900 parts by mass of propylene glycol monomethyl ether acetate each as a solvent, and filtering the obtained solution through a filter having a pore size of 0.2 μm.

[Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Limited), and thereafter heating was conducted at 250° C. for 60 sec to form an organic underlayer film having an average thickness of 100 nm. Each silicon-containing composition for EUV exposure prepared as described above was applied on the organic underlayer film, and subjected to heating at 220° C. for 60 sec, followed by cooling at 23° C. for 30 sec to form a silicon-containing film having an average thickness of 20 nm. A resist composition for EUV exposure (R-1) was applied on each silicon-containing film formed as described above, and heating was conducted at 130° C. for 60 sec, followed by cooling at 23° C. for 30 sec to form a resist film having an average thickness of 50 nm. Next, the resist film was irradiated with extreme ultraviolet rays using an EUV scanner (“TWINSCAN NXE:3300B”, available from ASML Co. (NA=0.3; Sigma=0.9; quadrupole illumination, with a 1: 1 line and space mask having a line width of 25 nm in terms of a dimension on wafer)). After the irradiation with the extreme ultraviolet rays, the substrate was heated at 110° C. for 60 sec, followed by cooling at 23° C. for 60 sec. Thereafter, development was performed by a paddle method using a 2.38% by mass aqueous TMAH solution (20° C. to 25° C.), followed by washing with water and drying, thereby obtaining a substrate for evaluation having a resist pattern formed thereon. The scanning electron microscope was used for measuring the length of the resist pattern of the substrate for evaluation and observing the resist pattern. In the substrate for evaluation, an exposure amount at which a 1: 1 line and space pattern with a line width of 25 nm was formed was defined as an optimum exposure amount. The pattern rectangularity was evaluated as “A” (good) when the cross-sectional shape of the pattern was rectangular, “B” (slightly good) when trailing was present in the cross section of the pattern, and “C” (poor) when a residue (defect) was present in the pattern.

### [Film Removability]

Each silicon-containing composition for ArF exposure and each silicon-containing composition for EUV as described above were applied on a 12-inch silicon wafer, and subjected to heating at 220° C. for 60 sec, followed by cooling at 23° C. for 30 sec to form a silicon-containing film having an average thickness of 20 nm, respectively. Each substrate with a silicon-containing film obtained as described above was immersed in a removing liquid heated to 65° C. (25% by mass ammonia aqueous solution/30% by mass hydrogen peroxide water/water=1/1/5 (volume ratio) mixed aqueous solution) for 5 min, then washed with water, and dried to obtain a substrate for evaluation. The substrate with a silicon-containing film obtained as described above was immersed in a removing liquid heated to 65° C. (25% by mass ammonia aqueous solution/30% by mass hydrogen peroxide water/water=1/1/5 (volume ratio) mixed aqueous solution) for 10 min, then washed with water, and dried to obtain a substrate for evaluation. The cross section of each substrate for evaluation obtained as described above was observed using a field emission scanning electron microscope (“SU8220”, available from Hitachi High-Technologies Corporation), and evaluated as “A” (good) when the silicon-containing film did not remain in the case of the immersion of the substrate in the removing liquid for 5 min, “B” (slightly good) when the silicon-containing film remained in the case of the immersion of the substrate in the removing liquid for 5 min but the silicon-containing film did not remain in the case of the immersion of the substrate in the removing liquid for 10 min, and “C” (poor) when the silicon-containing film remained in the case of the immersion of the substrate in the removing liquid for 5 min and 10 min.

TABLE 3

| | | First | | Second | | | | | |
|---|---|---|---|---|---|---|---|---|---|
| | | polysiloxane | | polysiloxane | | Solvent | | Evaluation | |
| | | | Blending | | Blending | | Blending | | |
| | Silicon | | amount | | amount | | amount | | |
| | composition | | (parts by | | (parts by | | (parts by | Pattern | Film |
| | containing | Type | mass) | Type | mass) | Type | mass) | rectangularity | removability |
| Example 1 | J-1 | A-1 | 90 | B-1 | 10 | C-1 | 9900 | A | B |
| Example 2 | J-2 | A-2 | 90 | B-1 | 10 | C-1 | 9900 | A | A |
| Example 3 | J-3 | A-3 | 98 | B-1 | 2 | C-1 | 9900 | B | A |
| Example 4 | J-4 | A-3 | 95 | B-1 | 5 | C-1 | 9900 | A | A |
| Example 5 | J-5 | A-3 | 90 | B-1 | 10 | C-1 | 9900 | A | A |
| Example 6 | J-6 | A-3 | 80 | B-1 | 20 | C-1 | 9900 | A | A |
| Example 7 | J-7 | A-3 | 70 | B-1 | 30 | C-1 | 9900 | A | A |
| Example 8 | J-8 | A-3 | 60 | B-1 | 40 | C-1 | 9900 | A | A |
| Example 9 | J-9 | A-3 | 50 | B-1 | 50 | C-1 | 9900 | A | B |
| Example 10 | J-10 | A-3 | 90 | B-2 | 10 | C-1 | 9900 | A | A |
| Example 11 | J-11 | A-3 | 90 | B-3 | 10 | C-1 | 9900 | A | A |
| Example 12 | J-12 | A-3 | 90 | B-4 | 10 | C-1 | 9900 | A | A |
| Example 13 | J-13 | A-3 | 90 | B-5 | 10 | C-1 | 9900 | B | A |
| Example 14 | J-14 | A-3 | 90 | B-6 | 10 | C-1 | 9900 | B | A |
| Example 15 | J-15 | A-3 | 90 | B-7 | 10 | C-1 | 9900 | A | A |
| Example 16 | J-16 | A-3 | 90 | B-8 | 10 | C-1 | 9900 | B | A |
| Example 17 | J-17 | A-3 | 90 | B-9 | 10 | C-1 | 9900 | A | A |
| Example 18 | J-18 | A-3 | 90 | B-10 | 10 | C-1 | 9900 | B | A |
| Example 19 | J-19 | A-4 | 90 | B-1 | 10 | C-1 | 9900 | A | A |
| Example 20 | J-20 | A-5 | 90 | B-1 | 10 | C-1 | 9900 | A | A |
| Example 21 | J-21 | A-6 | 90 | B-1 | 10 | C-1 | 9900 | A | A |
| Example 22 | J-22 | A-7 | 90 | B-1 | 10 | C-1 | 9900 | B | A |
| Example 23 | J-23 | A-8 | 90 | B-1 | 10 | C-1 | 9900 | A | A |
| Example 24 | J-24 | A-9 | 90 | B-1 | 10 | C-1 | 9900 | A | A |
| Example 25 | J-25 | A-10 | 90 | B-1 | 10 | C-1 | 9900 | B | A |
| Example 26 | J-26 | A-11 | 90 | B-1 | 10 | C-1 | 9900 | A | A |
| Example 27 | J-27 | A-12 | 90 | B-1 | 10 | C-1 | 9900 | A | A |
| Example 28 | J-28 | A-13 | 90 | B-1 | 10 | C-1 | 9900 | A | A |
| Example 29 | J-29 | A-14 | 90 | B-1 | 10 | C-1 | 9900 | A | B |
| Example 30 | J-30 | A-15 | 90 | B-1 | 10 | C-1 | 9900 | A | B |
| Example 31 | J-31 | A-16 | 90 | B-1 | 10 | C-1 | 9900 | A | B |
| Example 32 | J-32 | A-17 | 90 | B-1 | 10 | C-1 | 9900 | A | B |
| Example 33 | J-33 | A-18 | 90 | B-1 | 10 | C-1 | 9900 | A | B |
| Example 34 | J-34 | A-19 | 90 | B-1 | 10 | C-1 | 9900 | A | A |
| Example 35 | J-35 | A-20 | 90 | B-1 | 10 | C-1 | 9900 | A | A |
| Example 36 | J-36 | A-21 | 90 | B-1 | 10 | C-1 | 9900 | A | A |
| Example 37 | J-37 | A-22 | 90 | B-1 | 10 | C-1 | 9900 | A | A |
| Example 38 | J-38 | A-23 | 90 | B-1 | 10 | C-1 | 9900 | A | A |
| Comparative | J-1 | — | — | B-1 | 100 | C-1 | 9900 | A | C |
| Example 1 | | | | | | | | | |
| Comparative | J-2 | A-3 | 100 | — | — | C-1 | 9900 | C | A |
| Example 2 | | | | | | | | | |

As is apparent from the results in the above Table 3, the silicon-containing films formed from the silicon-containing compositions of Examples could form a resist pattern having more excellent cross-sectional shape rectangularity on the film than that of the silicon-containing films formed from the silicon-containing compositions of Comparative Examples. Furthermore, the silicon-containing films formed from the silicon-containing compositions of Examples had better film removability than that of the silicon-containing films formed from the silicon-containing compositions of Comparative Examples.

A silicon-containing composition and a method for manufacturing a semiconductor substrate of the present disclosure can form a silicon-containing film capable of forming a resist pattern having excellent cross-sectional shape rectangularity and capable of being easily removed. Therefore, these can be suitably used for manufacturing the semiconductor substrate and the like.

Obviously, numerous modifications and variations of the present invention are possible in light of the above teachings. It is therefore to be understood that within the scope of the appended claims, the invention may be practiced otherwise than as specifically described herein.

What is claimed is:

1. A silicon-containing composition comprising:
a first polysiloxane;
a second polysiloxane different from the first polysiloxane; and
a solvent,
the first polysiloxane comprising a group which comprises at least one selected from the group consisting of an ester bond, a carbonate structure, and a cyano group, and
the second polysiloxane comprising a substituted or unsubstituted hydrocarbon group having 1 to 20 carbon atoms.

2. The silicon-containing composition according to claim 1, wherein the first polysiloxane comprises a first structural unit represented by formula (1): 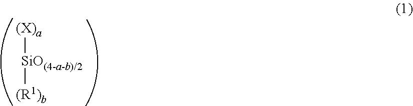
wherein, in the formula (1), X is a group comprising at least one selected from the group consisting of an ester bond, a carbonate structure, and a cyano group, a is an integer of 1 to 3, when a is 2 or more, a plurality of Xs are the same or different from each other, R¹ is a monovalent organic group having 1 to 20 carbon atoms, a hydroxy group, or a halogen atom, b is an integer of 0 to 2, when b is 2, two R¹s are the same or different from each other, and a +b is 3 or less.

3. The silicon-containing composition according to claim 2, wherein X in the formula (1) comprises the ester bond.

4. The silicon-containing composition according to claim 2, wherein X in the formula (1) is represented by formula (2): 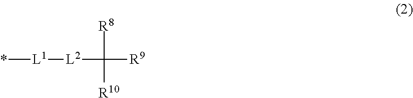
wherein L¹ in the formula (2) is a single bond or a divalent linking group, * is a bond with a silicon atom in the formula (1), L² is **—OCO —or **—OCO—, ** is a bond with L¹, R⁸ is a hydrogen atom or a monovalent hydrocarbon group having 1 to 20 carbon atoms, and R⁹ and R¹⁰ each independently represent a monovalent chain hydrocarbon group having 1 to 10 carbon atoms or a monovalent alicyclic hydrocarbon group having 3 to 20 carbon atoms, or R⁹ and R¹⁰ taken together represent a divalent alicyclic group having 3 to 20 carbon atoms together with the carbon atom to which R⁹ and R¹⁰ are bonded.

5. The silicon-containing composition according to claim 2, wherein a content of the first structural unit relative to all structural units constituting the first polysiloxane is 0.5 mol % or more and 40 mol % or less.

6. The silicon-containing composition according to claim 1, wherein the second polysiloxane comprises a second structural unit represented by formula (7): 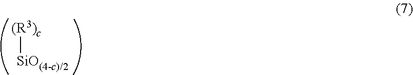
wherein, in the formula (7), R² is a substituted or unsubstituted alkyl group having 1 to 10 carbon atoms, c is an integer of 1 to 3, and when c is 2 or more, a plurality of Res are the same or different from each other.

7. The silicon-containing composition according to claim 6, wherein a content of the second structural unit relative to all structural units constituting the second polysiloxane is 10 mol % or more and 100 mol % or less.

8. The silicon-containing composition according to claim 1, wherein the first polysiloxane comprises a third structural unit represented by formula (5): 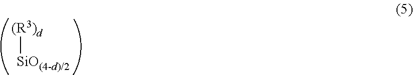
wherein, in the formula (5), R³ is a substituted or unsubstituted aryl group having 6 to 20 carbon atoms, d is an integer of 1 to 3, and when d is 2 or more, a plurality of R³s are the same or different from each other.

9. The silicon-containing composition according to claim 8, wherein a content of the third structural unit relative to all structural units constituting the first polysiloxane is 5 mol % or more and 50 mol % or less.

10. The silicon-containing composition according to claim 1, wherein the first polysiloxane comprises a fourth structural unit represented by formula (6): 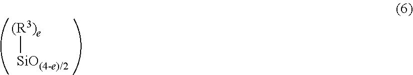
wherein, in the formula (6), R⁴ is a substituted or unsubstituted monovalent alkoxy group having 1 to 20 carbon atoms, a hydroxy group, or a halogen atom, e is an integer of 0 to 3, and when e is 2 or more, a plurality of R⁴s are the same or different from each other.

11. The silicon-containing composition according to claim 10, wherein a content of the fourth structural unit relative to all structural units constituting the first polysiloxane is 40 mol % or more and 95 mol % or less.

12. The silicon-containing composition according to claim 1, wherein a content of the first polysiloxane relative to a total mass of the first polysiloxane and the second polysiloxane is 40% by mass or more and 99% by mass or less.

13. The silicon-containing composition according to claim 1, wherein a content of the second polysiloxane relative to a total mass of the first polysiloxane and the second polysiloxane is 1% by mass or more and 60% by mass or less.

14. The silicon-containing composition according to claim 1, wherein the silicon-containing composition is suitable for forming a resist underlayer film in a method comprising: forming a pattern of the resist underlayer film, and performing etching using the patten as a mask, and removing the pattern by a basic liquid.

15. The silicon-containing composition according to claim 6, wherein in the formula (7), R² is an alkyl group having 1 to 10 carbon atoms, which is unsubstituted or substituted with a fluorine atom, a chlorine atom, a bromine atom, or an iodine atom.

16. A method for manufacturing a semiconductor substrate, comprising:
directly or indirectly applying the silicon-containing composition according to claim 1 to a substrate to form a silicon-containing film;
directly or indirectly applying a composition for forming a resist film to the silicon-containing film to form the resist film;
exposing the resist film to radiation;
developing the exposed resist film to form a resist pattern;
etching the silicon-containing film using the resist pattern as a mask to form a silicon-containing film pattern;
performing etching using the silicon-containing film pattern as a mask; and
removing the silicon-containing film pattern by a basic liquid.

17. The method according to claim 16, further comprising directly or indirectly forming an organic underlayer film on the substrate before the silicon-containing film is formed.

18. The method according to claim 16, wherein the basic liquid comprises: a base compound; water; and optionally hydrogen peroxide.
